(19) United States
(12) Patent Application Publication
(10) Pub. No.: US 2023/0143787 A1
(43) Pub. Date: May 11, 2023

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventor: Takeyoshi NISHIMURA, Matsumoto-city (JP)

(21) Appl. No.: 17/952,285

(22) Filed: Sep. 25, 2022

(30) Foreign Application Priority Data
Nov. 9, 2021 (JP) 2021-182858

(51) Int. Cl. H01L 27/12; H01L 23/34; H01L 21/84; G01K 1/02; G01K 7/01

(52) U.S. Cl. CPC H01L 27/1207; H01L 23/34; H01L 21/84; G01K 1/026; G01K 7/01

(57) ABSTRACT

A semiconductor device includes a temperature sensing unit including a plurality of temperature sensing diode portions each including an anode portion provided above a front surface of a semiconductor substrate and a cathode portion coupled to the anode portion and connected in series and a resistance portion of an N type electrically connected to the temperature sensing diode portion. A sum of resistance values of the cathode portion and the resistance portion is greater than a resistance value of the anode portion.

The contents of the following Japanese patent application(s) are incorporated herein by reference:

NO. 2021-182858 filed in JP on Nov. 9, 2021

### BACKGROUND

### 1. Technical Field

The present invention relates to a semiconductor device and a manufacturing method of the semiconductor device.

### 2. Related Art

Conventionally, there is known a technique of providing a temperature sensor on a semiconductor substrate on which a semiconductor element such as a metal oxide semiconductor field effect transistor (MOSFET) is formed (see, for example, Patent Documents 1 and 2).
Patent Document 1: Japanese Patent Application Publication No. 7-153920
Patent Document 2: Japanese Patent Application Publication No. 2010-129707

### BRIEF DESCRIPTION OF THE DRAWINGS

FIG. 1 illustrates an example of a top view of a semiconductor device 100 according to an example.

FIG. 2 illustrates an example of an XZ cross-sectional view of the semiconductor device 100.

FIG. 3A illustrates an example of a top view of a temperature sensing unit 178 according to the example.

FIG. 3B illustrates an example of a cross-sectional view taken along line A-A′ of FIG. 3A.

FIG. 3C illustrates an example of a cross-sectional view taken along line B-B′ of FIG. 3A.

FIG. 3D illustrates an example of an equivalent circuit of the semiconductor device 100.

FIG. 4A illustrates a top view of a temperature sensing diode portion according to a comparative example.

FIG. 4B illustrates an equivalent circuit of a semiconductor device according to the comparative example.

FIG. 5A illustrates temperature dependency of a forward voltage of a temperature sensing diode portion 173.

FIG. 5B illustrates temperature dependency of polysilicon resistances of a P type and an N type.

FIG. 5C illustrates the temperature dependency of the forward voltage of the temperature sensing diode portion 173 connected to a resistance portion of the P type.

FIG. 5D illustrates the temperature dependency of the forward voltage of the temperature sensing diode portion 173 connected to a resistance portion of the N type.

FIG. 6A illustrates another example of the top view of the temperature sensing unit 178 according to the example.

FIG. 6B illustrates another example of the equivalent circuit of the semiconductor device 100.

FIG. 6C illustrates another example of the top view of the temperature sensing unit 178 according to the example.

FIG. 7A illustrates still another example of the top view of the temperature sensing unit 178 according to the example.

FIG. 7B illustrates an example of a cross-sectional view taken along line B-B′ of FIG. 7A.

FIG. 7C illustrates another example of the cross-sectional view taken along line B-B′ of FIG. 7A.

FIG. 7D illustrates still another example of the cross-sectional view taken along line B-B′ of FIG. 7A.

FIG. 7E illustrates still another example of the cross-sectional view taken along line B-B′ of FIG. 7A.

FIG. 8A illustrates another example of the top view of the temperature sensing unit 178 according to the example.

FIG. 8B illustrates another example of the equivalent circuit of the semiconductor device 100.

FIG. 9A illustrates another example of the top view of the temperature sensing unit 178 according to the example.

FIG. 9B illustrates another example of the equivalent circuit of the semiconductor device 100.

FIG. 10A illustrates an example of a top view of a semiconductor device 200 according to the example.

FIG. 10B illustrates an example of an XZ cross-sectional view of the semiconductor device 200.

FIG. 11A illustrates an example of a manufacturing method of the semiconductor device 100.

FIG. 11B illustrates an example of the manufacturing method of the semiconductor device 100.

FIG. 12 illustrates another example of the manufacturing method of the semiconductor device 100.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to the solution of the invention.

As used in the present specification, one side in a direction parallel to a depth direction of a semiconductor substrate is referred to as “front” or “upper” and the other side is referred to as “back” or “lower”. One surface of two principal surfaces of a substrate, a layer, or other member is referred to as an upper surface, and the other surface is referred to as a lower surface. “Front”, “upper”, “back”, and “lower” directions are not limited to a direction of gravity, or directions in which a semiconductor device is mounted.

In the present specification, technical matters may be described using orthogonal coordinate axes of an X axis, a Y axis, and a Z axis. The orthogonal coordinate axes merely specify relative positions of components, and do not limit a particular direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis. In addition, in the present specification, viewing from the +Z axis direction may be referred to as a top view.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. Note that each conductivity type of each doping region may be the opposite polarity. In addition, in the present specification, the description of a P+ type or an N+ type means a higher doping concentration than that of the P type or the N type, and the description of a P-type or an N−type means a lower doping concentration than that of the P type or the N type.

In the present specification, the doping concentration refers to the concentration of impurities activated as donors or acceptors. In the present specification, the concentration difference between the donor and the acceptor may be set as the higher concentration of the donor or the acceptor. The concentration difference can be measured by capacitance-voltage profiling (CV profiling). In addition, the carrier concentration measured by spreading resistance profiling method (SR) may be set as the donor or acceptor concentration. In addition, in a case where the concentration distribution of the donor or acceptor has a peak, the peak value may be set as the concentration of the donor or acceptor in the region. In a case where the concentration of the donor or acceptor in the region where the donor or acceptor is present is approximately uniform or the like, the average value of the donor concentration or acceptor concentration in the region may be set as the donor concentration or acceptor concentration.

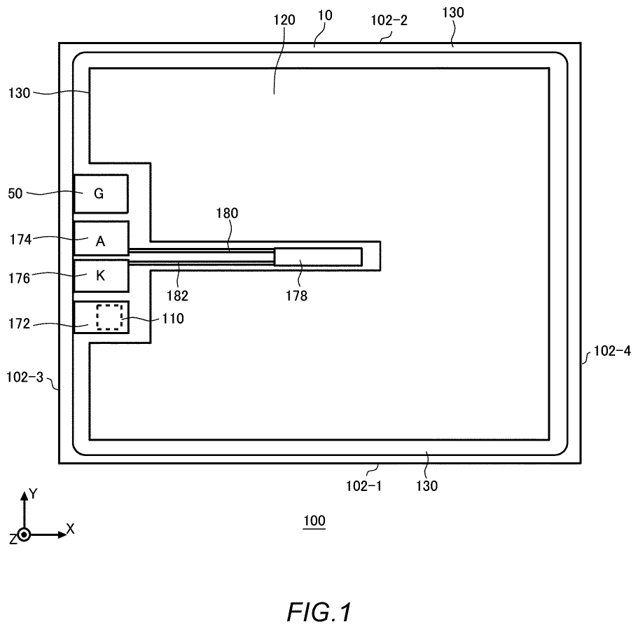

FIG. 1 illustrates an example of a top view of a semiconductor device 100 according to an example. The semiconductor device 100 includes a semiconductor substrate 10, a gate pad 50, a current sensing pad 172, a temperature sensing unit 178, and an anode pad 174 and a cathode pad 176 electrically connected to the temperature sensing unit 178.

The semiconductor substrate 10 has an end side 102. In the present specification, a direction of one end side 102-1 of the semiconductor substrate 10 in the top view of FIG. 1 is defined as an X axis, and a direction perpendicular to the X axis is defined as a Y axis. In the present example, the X axis is taken in the direction of the end side 102-1. In addition, a direction perpendicular to an X axis direction and a Y axis direction and forming a right-handed system is referred to as a Z axis direction. The temperature sensing unit 178 of the present example is provided in the +Z axis direction of the semiconductor substrate 10.

The semiconductor substrate 10 is made of a semiconductor material such as silicon semiconductor or a compound semiconductor. In the semiconductor substrate 10, a side on which the temperature sensing unit 178 is provided is referred to as a front surface, and a surface on the opposite side is referred to as a back surface. In the present specification, a direction connecting the front surface and the back surface of the semiconductor substrate 10 is referred to as a depth direction. The semiconductor substrate 10 of the present example has a substantially rectangular shape on the front surface, but may have a different shape.

The semiconductor substrate 10 has an active portion 120 on the front surface. The active portion 120 is a region through which a main current flows in the depth direction between the front surface and the back surface of the semiconductor substrate 10 when the semiconductor device 100 is turned on. A gate conductive portion 44, which will be described below, of the active portion 120 is connected to the gate pad 50 by a gate runner.

The active portion 120 may be provided with a transistor portion 70 such as a metal oxide semiconductor field effect transistor (MOSFET).

The semiconductor device 100 has a well region 130 of the P type outside the active portion 120 on the front surface. The semiconductor device has an edge termination structure portion on the further outside. The edge termination structure portion includes, for example, a guard ring and a field plate that are annularly provided to surround the active portion 120, and a structure that is a combination of the guard ring and the field plate.

The temperature sensing unit 178 may be arranged in a wide portion provided near the center of the front surface of the semiconductor substrate 10. The active portion 120 is not provided in the wide portion. Integration of the active portion 120 of the semiconductor substrate 10 causes the central portion of the semiconductor substrate 10 to be easily heated by heat generated from a switching element formed in the active portion 120. Providing the temperature sensing unit 178 in the wide portion near the center allows for monitoring of the temperature of the transistor portion 70. This can prevent the transistor portion 70 from being overheated beyond a junction temperature Tj which is a normal operating temperature range.

The temperature sensing unit 178 has a plurality of temperature sensing diode portions to be described below. The temperature sensing diode portion includes an anode wiring 180 electrically connected to an anode portion and a cathode wiring 182 electrically connected to a cathode portion. The anode wiring 180 and the cathode wiring 182 are wirings containing metal such as aluminum or an alloy containing aluminum.

The anode pad 174 and the cathode pad 176 are provided in an outer peripheral region of the active portion 120. The anode pad 174 is connected to the temperature sensing unit 178 via the anode wiring 180. The cathode pad 176 is connected to the temperature sensing unit 178 via the cathode wiring 182. In FIG. 1, the anode pad 174 and the cathode pad 176 are provided to be arranged side by side along an end side 102-3, and the anode wiring 180 and the cathode wiring 182 extend in the X axis direction. The anode pad 174 and the cathode pad 176 are electrodes containing metal such as aluminum or an alloy containing aluminum.

The current sensing pad 172 is provided in the outer peripheral region of the active portion 120. The current sensing pad 172 may be provided to be aligned with the gate pad 50, the anode pad 174, and the cathode pad 176 along the Y axis direction (the end side 102-3 in FIG. 1). The current sensing pad 172 is electrically connected to a current sensing unit 110. The current sensing pad 172 is an example of a front surface electrode. The current sensing unit 110 has a structure similar to that of the transistor portion 70 of the active portion 120, and simulates the operation of the transistor portion 70. A current proportional to the current flowing through the transistor portion 70 flows through the current sensing unit 110. This allows the current flowing through the transistor portion 70 to be monitored.

The current sensing unit 110 is provided with a gate trench portion. The gate trench portion of the current sensing unit 110 is electrically connected to the gate runner. Unlike the transistor portion 70, the gate trench portion may have a portion where a source region 12 to be described below is not provided.

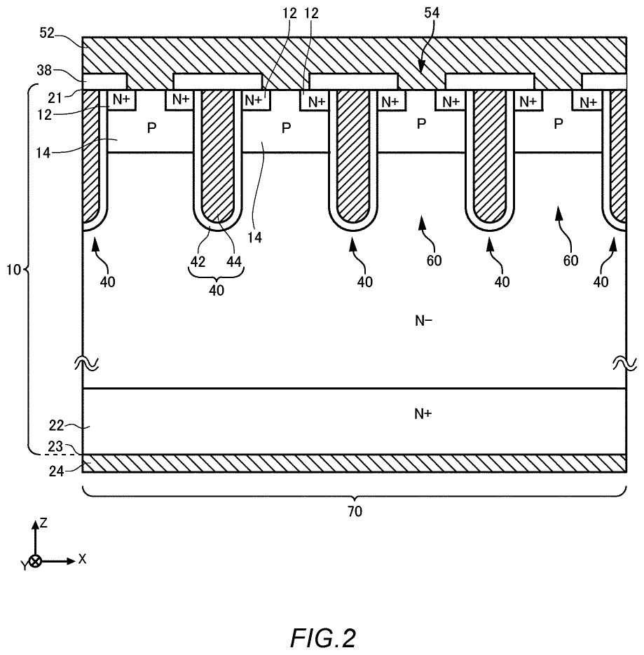

FIG. 2 illustrates an example of an XZ cross-sectional view of the semiconductor device 100. FIG. 2 illustrates an example of an XZ cross-sectional view of an element structure in the transistor portion 70 of the active portion 120. The transistor portion 70 may be provided on the entire surface of the active portion 120 of the present example.

The transistor portion 70 has a plurality of gate trench portions 40 on the front surface 21 of the semiconductor substrate 10. In addition, the semiconductor substrate 10 has a mesa portion 60 between the plurality of trench portions. The mesa portion 60 is connected to a source electrode 52 via a contact hole 54.

The gate trench portion 40 includes the gate conductive portion 44 composed of a conductor such as metal, and a gate insulating film 42. The gate conductive portion 44 is insulated from the source electrode 52 by an interlayer insulating film 38. The gate conductive portion 44 is electrically connected to the gate pad 50 by the gate runner and set to have a gate potential. The gate conductive portion 44 corresponds to the gate electrode of the transistor portion 70. As an example, the gate potential may be higher than a source potential.

The transistor portion 70 includes, in order from the front surface 21 side of the semiconductor substrate 10, a source region 12 of a first conductivity type, a base region 14 of a second conductivity type, a drift region 18 of the first conductivity type, and a drain region 22 of the first conductivity type. The source region 12 may be provided over the entire active portion 120 on the front surface 21 of the semiconductor substrate 10 and provided in contact with the gate trench portion 40. The base region 14 may be exposed to the front surface 21 between adjacent source regions 12 in the active portion 120. As a result, the base region 14 and the source region 12 are connected to the source electrode 52 via the contact hole 54.

In addition, in the mesa portion 60, a contact region (not illustrated) of the second conductivity type may be provided between the source regions 12 adjacent to each other with the base region 14 interposed therebetween, and the contact region and the source electrode 52 may be connected to the source electrode 52 via the contact hole 54.

As an example, the source region 12 has an N+ type polarity. That is, in the present example, the first conductivity type is the N type, and the second conductivity type is the P type. However, the first conductivity type may be the P type, and the second conductivity type may be the N type. In this case, each of the conductivity types of the substrate, the layer, the region, and the like in each example is of the opposite polarity.

The base region 14 of the present example has a P type polarity. When the gate conductive portion 44 is set to have the gate potential, electrons are attracted toward the gate trench portion 40 in the base region 14. A channel of the N type is formed in a region of the base region 14 in contact with the gate trench portion 40, and is driven as a transistor.

A drift region 18 of the N−type is provided below the base region 14. A drain region 22 of the N+ type is provided below the drift region 18.

The lower surface of the drain region 22 corresponds to the back surface 23 of the semiconductor substrate 10. The drain electrode 24 is provided on the back surface 23 of the semiconductor substrate 10. The drain electrode 24 is formed of a conductive material such as metal, or provided by stacking conductive materials such as metal.

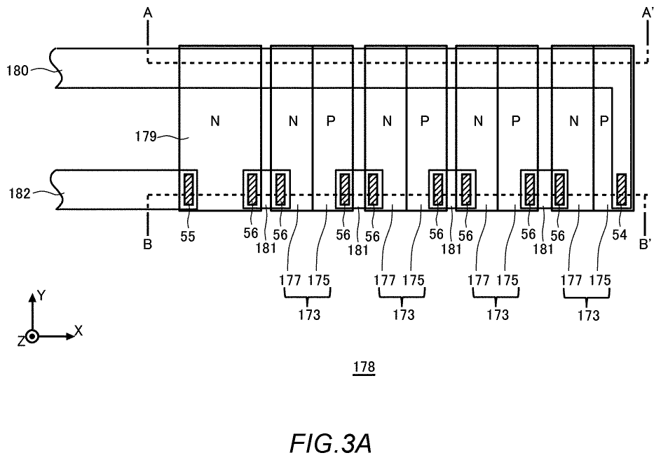

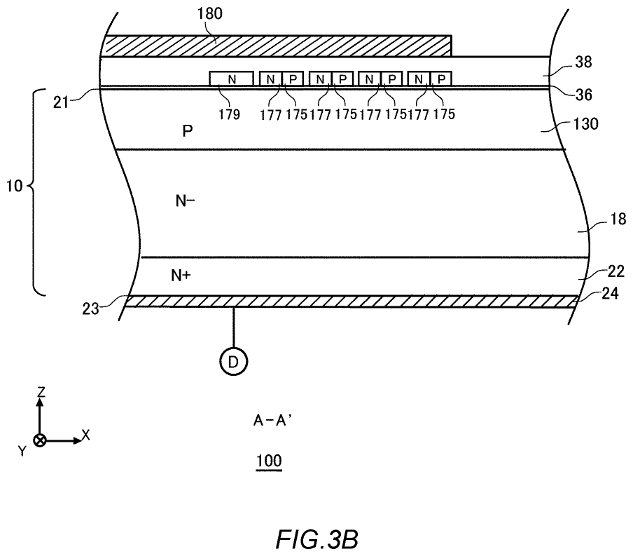

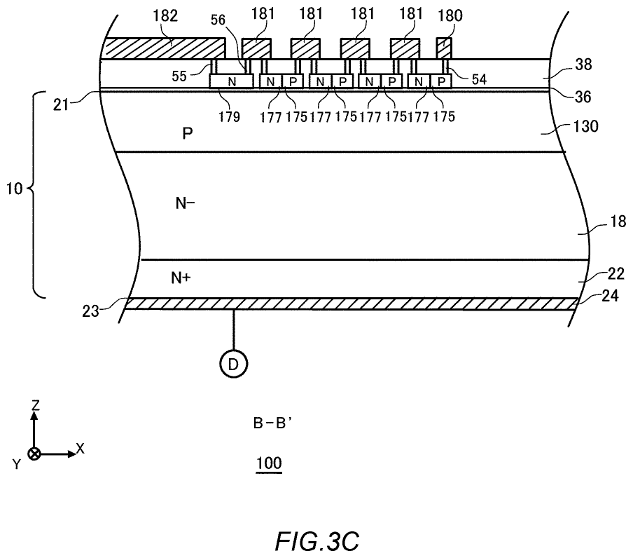

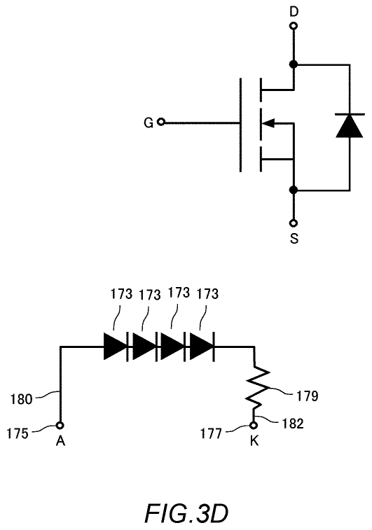

FIG. 3A illustrates an example of a top view of the temperature sensing unit 178 according to the example. The temperature sensing unit 178 of the present example is provided above the front surface 21 of the semiconductor substrate 10. The temperature sensing unit 178 includes a temperature sensing diode portion 173 connected in series, and a resistance portion 179 of the N type electrically connected to the temperature sensing diode portion 173.

The temperature sensing diode portion 173 includes an anode portion 175 of the P type and a cathode portion 177 of the N type coupled (joined) to the anode portion 175. The anode portion 175 may be polysilicon doped with boron (B). The cathode portion 177 may be polysilicon doped with arsenic (As), phosphorus (P), or the like. The doping concentration of the anode portion 175 and the cathode portion 177 may be greater than or equal to 1E18 cm⁻³ and less than 1E20 cm⁻³. The anode portion 175 and the cathode portion 177 have substantially the same dimensions. In FIG. 3A, four temperature sensing diode portions 173 are connected in series along the X axis direction.

The resistance portion 179 of the present example is polysilicon of the N type. The resistance portion 179 may be polysilicon doped with arsenic (As), phosphorus (P), or the like. The doping concentration of the resistance portion 179 may be greater than or equal to 1E18 cm⁻³ and less than 1E20 cm⁻³.

The doping concentration of the resistance portion 179 of the present example is equal to or less than the doping concentration of the cathode portion 177. The doping concentration of the resistance portion 179 may be the same as the doping concentration of the cathode portion 177.

The resistance portion 179 of the present example is provided between the cathode wiring 182 and the temperature sensing diode portion 173, and is connected in series with the temperature sensing diode portion 173. The resistance portion 179 has substantially the same dimensions as the anode portion 175 and the cathode portion 177.

A connection portion 181 for connecting the temperature sensing diode portion 173 and the resistance portion 179 adjacent to each other is provided above the temperature sensing unit 178. In FIG. 3A, the connection portion 181 is provided above the vicinity of the end portions of the temperature sensing diode portion 173 and the resistance portion 179 in the −Y axis direction. The connection portion 181 is a member containing metal such as aluminum or an alloy containing aluminum.

The temperature sensing diode portions 173 and the resistance portion 179 are connected to the connection portions 181 via contact holes 56 provided to penetrate interlayer insulating film 38, and are connected to each other via the connection portions 181. Note that the interlayer insulating film 38 is omitted in FIG. 3A.

The temperature sensing unit 178 is connected to each of the anode pad 174 and the cathode pad 176 via the anode wiring 180 and the cathode wiring 182. In FIG. 3A, the anode wiring 180 is connected to the anode portion 175 of the temperature sensing diode portion 173 farthest from the anode pad 174 (in +X axis direction) via the contact hole 54 provided to penetrate the interlayer insulating film 38. In addition, the cathode wiring 182 is connected to the resistance portion 179 via a contact hole 55 provided to penetrate the interlayer insulating film 38, and the resistance portion 179 is connected to the cathode portion 177 of the closest temperature sensing diode portion 173 via the contact hole 56 and the connection portion 181.

FIG. 3B illustrates an example of a cross-sectional view taken along line A-A′ of FIG. 3A. The cross-sectional view taken along line A-A′ is an XZ cross-sectional view passing through the anode wiring 180 and the temperature sensing unit 178. FIG. 3C illustrates an example of a cross-sectional view taken along line B-B′ of FIG. 3A. The cross-sectional view taken along line B-B′ is an XZ cross-sectional view passing through the cathode wiring 182 and the temperature sensing unit 178.

The temperature sensing unit 178 of the present example is provided above the well region 130. The anode portion 175 and the cathode portion 177 are arrayed on a surface parallel to the front surface 21 of the semiconductor substrate 10. The resistance portion 179, the anode portion 175, and the cathode portion 177 of the present example are provided on the first insulating film 36 provided on the front surface 21 of the semiconductor substrate 10, and the upper side and the side thereof are covered with the interlayer insulating film 38. The first insulating film 36 may be formed of the same oxide film as the gate insulating film 42.

The contact hole 54 and the contact hole 55 are positioned to be aligned with the contact hole 56 in the Y axis direction. In FIG. 3A, the contact hole 54, the contact hole 55, and the contact hole 56 are provided to be aligned in the extending direction of the cathode wiring 182.

FIG. 3D illustrates an example of an equivalent circuit of the semiconductor device 100. FIG. 3D illustrates an example of an element structure of the active portion 120 and a circuit configuration of the temperature sensing unit 178 illustrated in FIG. 3A. Note that both of them are insulated by the interlayer insulating film 38. The element structure of the active portion 120 in the present example is a MOSFET (metal oxide semiconductor field effect transistor).

A plurality of temperature sensing diode portions 173 and the resistance portion 179 in the present example are connected in series between the anode pad 174 and the cathode pad 176. The temperature sensing diode portion 173 may be a Zener diode including the anode portion 175 and the cathode portion 177.

The anode wiring 180 connects the anode pad 174 and the anode portion 175 of the temperature sensing diode portion 173, and the cathode wiring 182 connects the cathode pad 176 and the resistance portion 179. The resistance portion 179 of the present example is provided between the cathode wiring 182 and the temperature sensing diode portion 173.

In the circuit between the anode pad 174 and the cathode pad 176, the resistance of the metal wiring (the anode wiring 180, the cathode wiring 182, and the connection portion 181) is smaller by two order of magnitude than the resistance of polysilicon (the resistance portion 179, the anode portion 175, and the cathode portion 177). Accordingly, the resistance of this circuit depends substantially on the resistance of polysilicon.

The resistance of polysilicon depends on its dimensions and the doping concentration of impurities. In addition, as described above, the dimensions of the resistance portion 179, the anode portion 175, and the cathode portion 177 are substantially the same. In the temperature sensing unit 178 of the present example, the resistance value of an N type region is greater than the resistance value of a P type region. That is, the sum of the resistance values of the cathode portion 177 and the resistance portion 179 is greater than the resistance value of the anode portion 175.

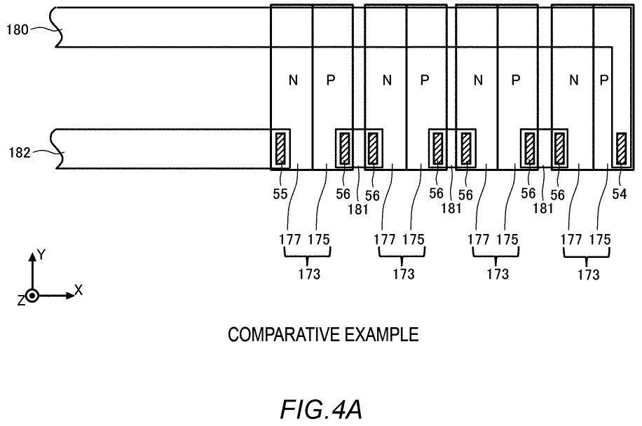

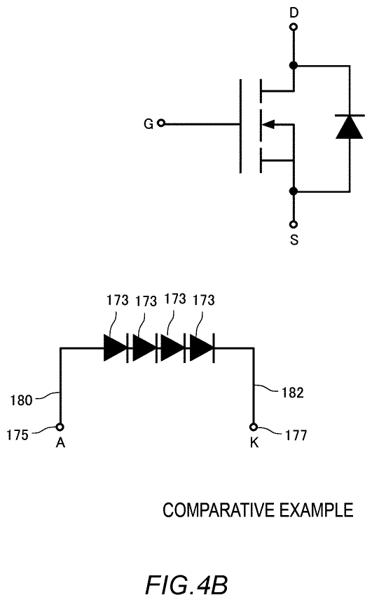

FIG. 4A illustrates a top view of a temperature sensing diode portion according to a comparative example. The configuration of the semiconductor device according to the comparative example is common to that of the semiconductor device 100 according to the example except that the resistance portion of the N type electrically connected to the temperature sensing diode portion is not provided. Therefore, in the description of the comparative example, the same reference numerals are given to elements whose configuration and function are common to those of the semiconductor device 100, and the description thereof will be omitted.

In the comparative example, a plurality of temperature sensing diode portions 173 is connected in series. The plurality of temperature sensing diode portions 173 is connected to each of the anode pad 174 and the cathode pad 176 via the anode wiring 180 and the cathode wiring 182. In FIG. 4A, the anode wiring 180 is connected to the anode portion 175 of the temperature sensing diode portion 173 farthest from the anode pad 174 (in +X axis direction) via the contact hole 54 provided to penetrate the interlayer insulating film 38. In addition, the cathode wiring 182 is connected to the cathode portion 177 of the temperature sensing diode portion 173 closest to the cathode pad 176 (in −X axis direction) via the contact hole 55 provided to penetrate the interlayer insulating film 38.

FIG. 4B illustrates an equivalent circuit of the semiconductor device according to the comparative example. In the comparative example, the resistance of the circuit between the anode pad 174 and the cathode pad 176 is substantially dependent on the resistance of the plurality of temperature sensing diode portions 173. In addition, in the plurality of temperature sensing diode portions 173, the resistance value of the N type region and the resistance value of the P type region are substantially the same. That is, the resistance value of the cathode portion 177 and the resistance value of the anode portion 175 are substantially the same.

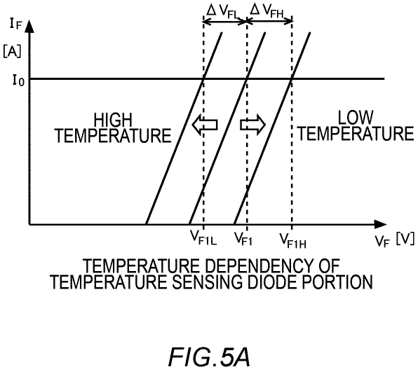

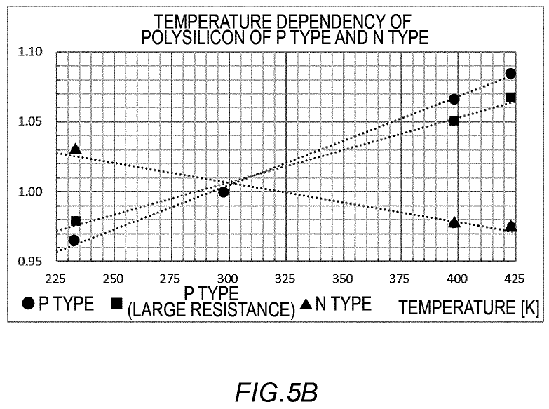

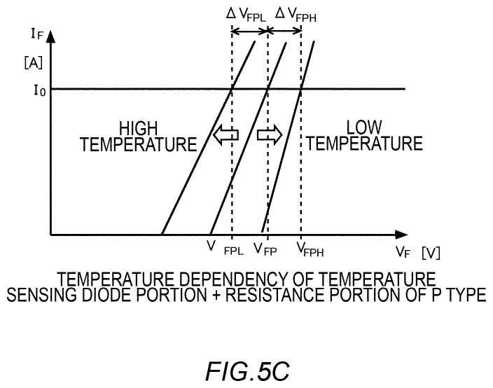

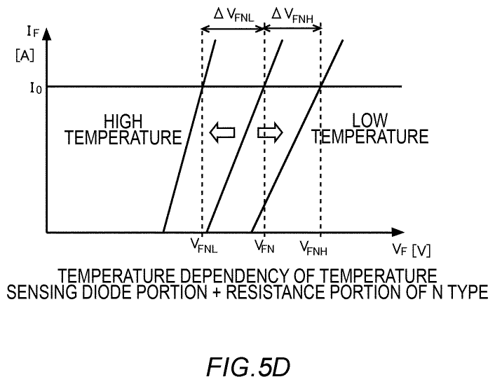

FIG. 5A illustrates temperature dependency of a forward voltage of the temperature sensing diode portion 173. FIG. 5A illustrates a graph in which a horizontal axis represents a forward voltage V_{F}[V], and a vertical axis represents a forward current I_{F}[A]. The forward voltage V_{F} is a voltage that drops when the forward current I_{F} flows through the temperature sensing diode portion 173.

The forward voltage V_{F} of the temperature sensing diode portion 173 formed of polysilicon has a characteristic of decreasing when the temperature increases and increasing when the temperature decreases, so-called negative temperature dependency. Assuming that a forward current at a reference temperature is I₀[A] and a forward voltage at the reference temperature is V_{F1}[V], a forward voltage V_{F1L} for a forward current I₀ is less than V_{F1} in a region having a temperature higher than the reference temperature, and a forward voltage V_{F1H} for the forward current I₀ is greater than V_{F1} in a region having a temperature lower than the reference temperature.

A variation amount ΔV_{F} from the forward voltage V_{F1} is converted into a temperature change amount and monitored. When ΔV_{F} exceeds a predetermined threshold, it is determined that a heat generation amount exceeds an assured value. Note that since ΔV_{F} is generally as small as 0.6 to 0.8 V, a method of connecting a plurality of temperature sensing diode portions 173 in series and measuring a total value of ΔV_{F} to improve detection sensitivity is adopted.

In the method of measuring the total value of ΔV_{F} of the plurality of temperature sensing diode portions 173, the measurement error included in each ΔV_{F} may be enlarged. On the other hand, in recent years, the semiconductor device 100 has been used in a hot region such as an engine room of a vehicle and in applications where highly accurate temperature detection is requested. Further, in view of an increasing request for safety, improvement in temperature detection accuracy is required in the semiconductor device 100.

FIG. 5B illustrates temperature dependency of polysilicon resistances of the P type and the N type. In FIG. 5B, a vertical axis represents a relative value (a ratio where a resistance value at the reference temperature is 1) with respect to the resistance value at the reference temperature (room temperature), and a horizontal axis represents a graph of a temperature [K].

As illustrated in FIG. 5B, in the polysilicon resistance of the P type (the legend is a circle and a square), the relative value of the reference temperature to the resistance value is proportional to the temperature. That is, in the polysilicon resistance of the P type, the resistance is proportional to the temperature, and has positive temperature dependency. In addition, when the polysilicon resistances of the P type having different resistances are compared with each other, the polysilicon resistance of the P type having a smaller resistance (the legend is a circle) has higher temperature dependency than the polysilicon resistance of the P type having a larger resistance (the legend is a square). Accordingly, the polysilicon resistance of the P type has temperature dependency opposite to the forward voltage V_{F} of the temperature sensing diode portion 173. Herein, in the present example, the temperature dependency of the resistance due to a difference in impurity concentration is shown in polysilicon having the same shape.

On the other hand, the polysilicon resistance of the N type (the legend is a triangle) is inversely proportional to the temperature. That is, in the polysilicon resistance of the N type, the resistance is inversely proportional to the temperature, and has negative temperature dependency. Accordingly, the polysilicon resistance of the N type has the same temperature dependency as the forward voltage V_{F} of the temperature sensing diode portion 173.

FIG. 5C illustrates the temperature dependency of the forward voltage of the temperature sensing diode portion 173 connected to a resistance portion of the P type. FIG. 5D illustrates the temperature dependency of the forward voltage of the temperature sensing diode portion 173 connected to a resistance portion of the N type. FIGS. 5C and 5D illustrate graphs in which a horizontal axis represents the forward voltage V_{F}[V], and a vertical axis represents the forward current I_{F}[A]. Herein, the connection of the temperature sensing diode portion 173 to the resistance portion of the N type means that the cathode portion 177 of the temperature sensing diode portion 173 is connected to the resistance portion of the polysilicon of the N type having similar dimensions, for example, as illustrated in FIG. 3A. In addition, the connection of the temperature sensing diode portion 173 to the resistance portion of the P type means that, for example, conversely to FIG. 3A, the anode portion 175 of the temperature sensing diode portion 173 is connected to the resistance portion of the polysilicon of the P type having similar dimensions.

As described above, the polysilicon resistance of the P type has temperature dependency opposite to the forward voltage V_{F} of the temperature sensing diode portion 173. Accordingly, as illustrated in FIG. 5C, in the temperature sensing diode portion 173 connected to the resistance portion of the P type, the gradient of V_{F}-I_{F} is small in a region having a temperature higher than the reference temperature, and the gradient of V_{F}-I_{F} is large in a region having a temperature lower than the reference temperature. Therefore, the variation amount ΔV_{F} of the forward voltage V_{F} in the forward current I₀ is less than ΔV_{F} of the temperature sensing diode portion 173 illustrated in FIG. 5A.

On the other hand, the polysilicon resistance of the N type has the same temperature dependency as the forward voltage V_{F} of the temperature sensing diode portion 173. Accordingly, as illustrated in FIG. 5D, in the temperature sensing diode portion 173 connected to the resistance portion of the N type, the gradient of the V_{F} is large in a region having a temperature higher than the reference temperature, and the gradient of V_{F}-I_{F} is small in a region having a temperature lower than the reference temperature. Therefore, the variation amount ΔV_{F} of the forward voltage V_{F} in the forward current I₀ is greater than ΔV_{F} of the temperature sensing diode portion 173 illustrated in FIG. 5A.

In this manner, the temperature sensing unit 178 of the present example has the resistance portion 179 of the N type having the same temperature dependency as the forward voltage V_{F} of the temperature sensing diode portion 173, and since the resistance value of the N type region is larger than the resistance value of the P type region, the variation amount ΔV_{F} of the forward voltage V_{F} in the forward current I₀ increases, and the temperature detection accuracy can be improved.

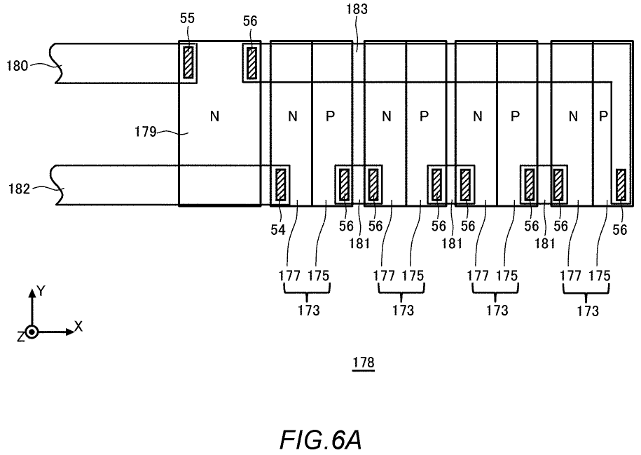

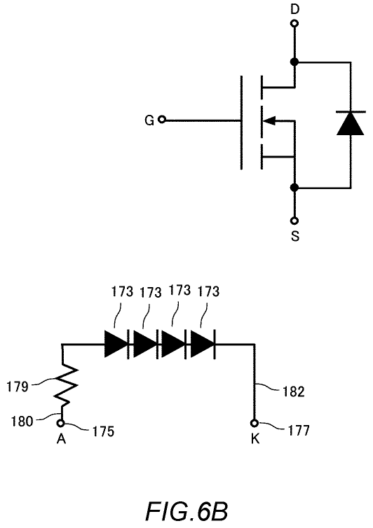

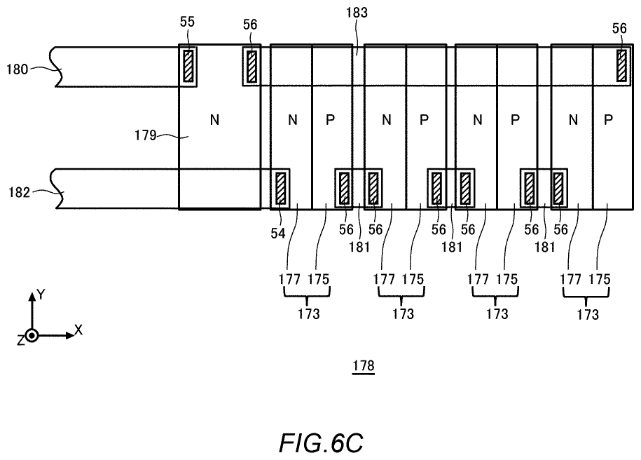

FIG. 6A illustrates another example of the top view of the temperature sensing unit 178 according to the example. FIG. 6B illustrates another example of the equivalent circuit of the semiconductor device 100. FIG. 6B illustrates an example of the equivalent circuit corresponding to the semiconductor device 100 including the temperature sensing unit 178 of FIG. 6A. In the description of FIG. 6A, the description of elements common to those of FIG. 3A is omitted.

In FIG. 6A, the contact hole 54 and the contact hole 56 provided on the temperature sensing diode portion 173 are provided to be aligned in an extending direction (+X axis direction) of the cathode wiring 182. In addition, the contact hole 55 and the contact hole 56 provided on the resistance portion 179 are provided to be arranged side by side in the extending direction (+X axis direction) of the anode wiring 180.

The cathode wiring 182 is connected to the cathode portion 177 of the temperature sensing diode portion 173 closest to the cathode pad 176 via the contact hole 54. In addition, the anode wiring 180 is connected to the resistance portion 179 via the contact hole 55.

The resistance portion 179 is connected to the anode portion 175 of the temperature sensing diode portion 173 farthest from the anode pad 174 via the contact hole 56 and the connection portion 183. The resistance portion 179 is provided between the anode wiring 180 and the temperature sensing diode portion 173.

The connection portion 183 has an L shape, and has a portion extending in the extending direction (+X axis direction) of the anode wiring 180 and a portion extending from the anode wiring 180 side to the cathode wiring 182 side (−Y axis direction).

FIG. 6B illustrates an example of the equivalent circuit corresponding to the semiconductor device 100 including the temperature sensing unit 178 of FIG. 6A. FIG. 6B illustrates an example of an element structure of the active portion 120 and a circuit configuration of the temperature sensing unit 178 illustrated in FIG. 6A. Note that both of them are insulated by the interlayer insulating film 38. The element structure of the active portion 120 in the present example is a MOSFET (metal oxide semiconductor field effect transistor).

A plurality of temperature sensing diode portions 173 and the resistance portion 179 in the present example are connected in series between the anode pad 174 and the cathode pad 176. The temperature sensing diode portion 173 may be a Zener diode including the anode portion 175 and the cathode portion 177.

The cathode wiring 182 connects the cathode pad 176 and the cathode portion 177 of the temperature sensing diode portion 173, and the anode wiring 180 connects the anode pad 174 and the resistance portion 179. Although the present example is different from FIG. 3D in that the resistance portion 179 is provided between the anode wiring 180 and the temperature sensing diode portion 173, effects similar to those of FIGS. 3A to 3D can be obtained.

FIG. 6C illustrates another example of the top view of the temperature sensing unit 178 according to the example. The example of FIG. 6C is different from FIG. 6A in that the connection portion 183 has a rectangular shape. In FIG. 6C, the contact hole 54 and the contact hole 56, which are provided on the temperature sensing diode portion 173, except for a part thereof are provided to be aligned in the extending direction (+X axis direction) of the cathode wiring 182.

Note that the contact hole 56 provided on the anode portion 175 of the temperature sensing diode portion 173 located at the farthest position from the anode wiring 180 is provided in the extending direction (+X axis direction) of the anode wiring 180. In addition, the contact hole 55 and the contact hole 56 provided on the resistance portion 179 are provided to be arranged side by side in the extending direction (+X axis direction) of the anode wiring 180.

The cathode wiring 182 is connected to the cathode portion 177 of the closest (+X axis direction) temperature sensing diode portion 173 via the contact hole 54. In addition, the anode wiring 180 is connected to the resistance portion 179 via the contact hole 55. The resistance portion 179 is connected to the anode portion 175 of the temperature sensing diode portion 173 farthest from the anode pad 174 via the contact hole 56 and the connection portion 183. The resistance portion 179 is provided between the anode wiring 180 and the temperature sensing diode portion 173. Also in the present example, the same effects as those in FIGS. 3A to 3D can be obtained.

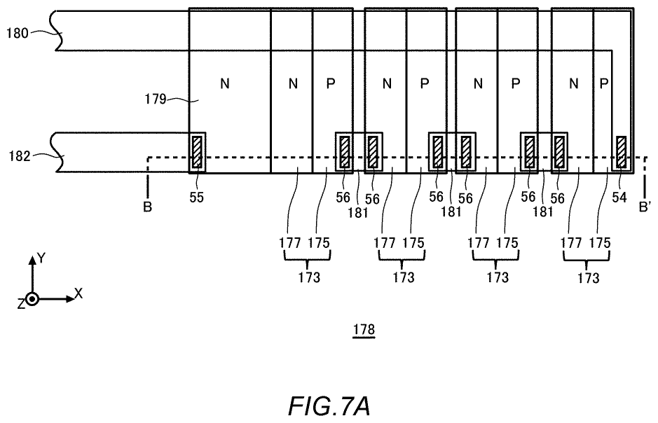

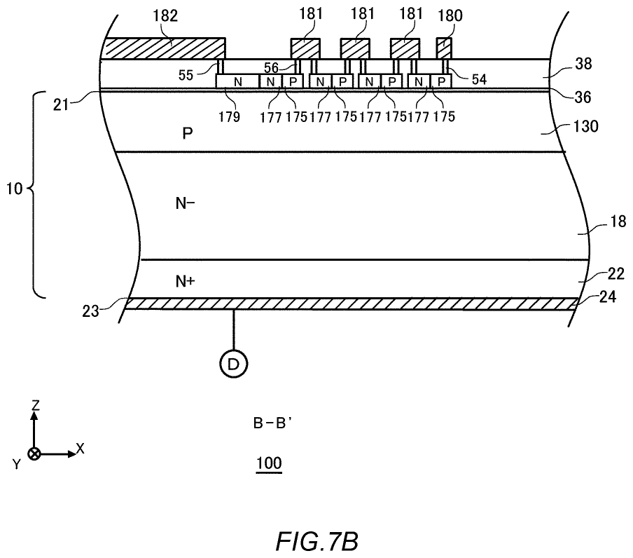

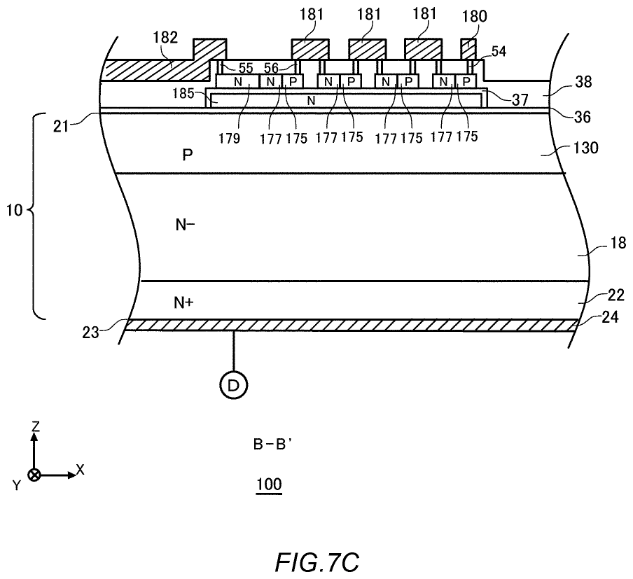

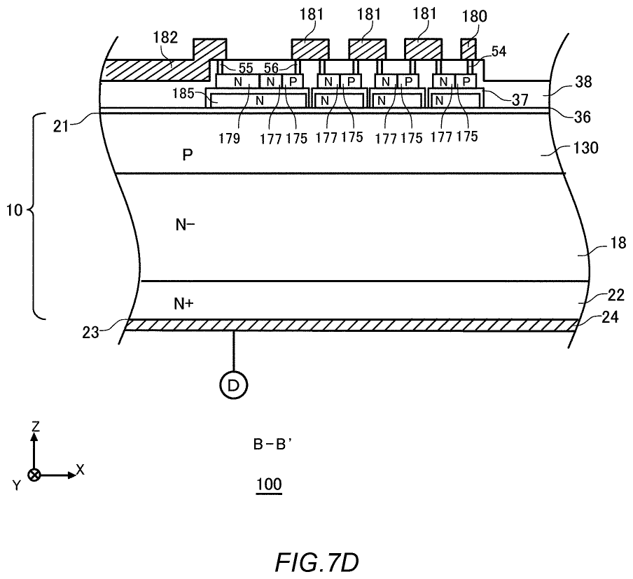

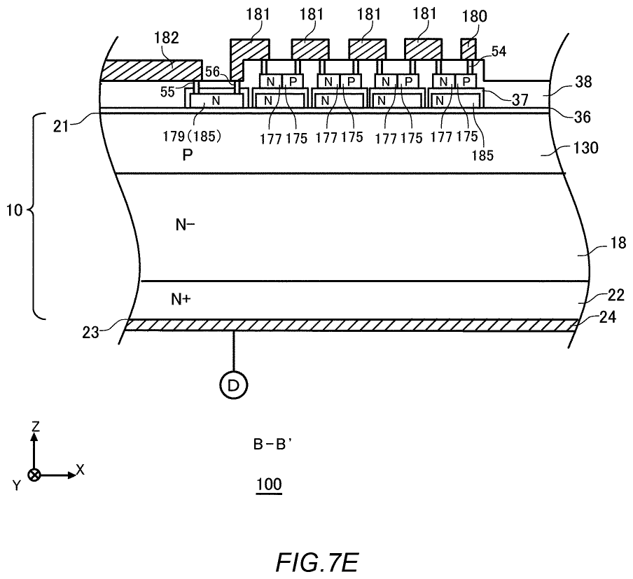

FIG. 7A illustrates another example of the top view of the temperature sensing unit 178 according to the example. In the description of FIGS. 7A and 7B, the description of elements common to those of FIG. 3A is omitted.

In FIG. 7A, the resistance portion 179 is provided to be coupled to the cathode portion 177. That is, the resistance portion 179 is provided integrally with the cathode portion 177 of the temperature sensing diode portion 173 closest to the cathode pad 176 (in −X axis direction). As a result, the X axis direction distance of the temperature sensing unit 178 is shortened, the area of the active portion 120 can be enlarged, and the number of the connection portions 181 and the contact holes 56 can be reduced.

In FIG. 7A, the contact hole 54, the contact hole 55, and the contact hole 56 are provided to be aligned in the extending direction of the cathode wiring 182 similarly to FIG. 3A, but may be provided to be aligned in the extending direction of the anode wiring line 180 similarly to FIG. 6A.

FIG. 7B illustrates an example of a cross-sectional view taken along line B-B′ of FIG. 7A. Similarly to the temperature sensing unit 178 of FIG. 3A, the temperature sensing unit 178 of the present example is provided on the first insulating film 36 provided on the front surface 21 of the semiconductor substrate 10 (see FIG. 3C).

FIG. 7C illustrates another example of the cross-sectional view taken along line B-B′ of FIG. 7A. The semiconductor device 100 of the present example further includes a conductive layer 185 provided on the first insulating film 36 and a second insulating film 37 covering the conductive layer 185, and the temperature sensing unit 178 is provided on the second insulating film 37.

The second insulating film 37 may be an oxide film formed by thermal oxidation or a CVD method. The conductive layer 185 is polysilicon of the N type. The conductive layer 185 may be formed of the same doped polysilicon as a dummy conductive portion 34 and the gate conductive portion 44. The doping concentration of the conductive layer 185 is 1E20 cm⁻³ or more.

In this manner, the conductive layer 185 is arranged between the first insulating film 36 and the second insulating film 37, and a Z axis direction distance from the front surface 21 of the semiconductor substrate 10 to the lower end of the temperature sensing diode portion 173 increases. As a result, a capacitive component is formed below the temperature sensing diode portion 173, and it is possible to prevent the temperature sensing diode portion 173 from being broken by static electricity or an overvoltage applied to the electrode.

FIG. 7D illustrates still another example of the cross-sectional view taken along line B-B′ of FIG. 7A. The semiconductor device 100 of the present example is common to that of FIG. 7C in including the conductive layer 185 and the second insulating film 37, but the conductive layer 185 has a plurality of regions which are arranged correspondingly to the temperature sensing diode portions 173 and the resistance portion 179 and divided from each other.

In this manner, by dividing the conductive layer 185, even when any of the plurality of temperature sensing diode portions 173 is broken, the influence remains only in the relevant temperature sensing diode portion 173, and short-circuiting of the other temperature sensing diode portions 173 can be prevented.

FIG. 7E illustrates still another example of the cross-sectional view taken along line B-B′ of FIG. 7A. The semiconductor device 100 of the present example is common to that of FIG. 7D in including the conductive layer 185 and the second insulating film 37, and in that the conductive layer 185 is divided into a plurality of regions. Note that, in the present example, the resistance portion 179 is provided not on the second insulating film 37 but on the first insulating film 36. That is, in the present example, either of the divided regions of the conductive layer 185 may be used as the resistance portion 179. In this manner, in a region where the conductive layer 185 also serves as the resistance portion 179, the thickness in the Z axis direction can be reduced.

By reducing the thickness in the Z axis direction, the resistance in the region where the conductive layer 185 also serves as the resistance portion 179 increases, and the area of the resistance portion 179 can be reduced. In addition, in the region where the conductive layer 185 also serves as the resistance portion 179, by reducing the length in the Y axis direction, the resistance is increased, and the area of the resistance portion 179 can be reduced.

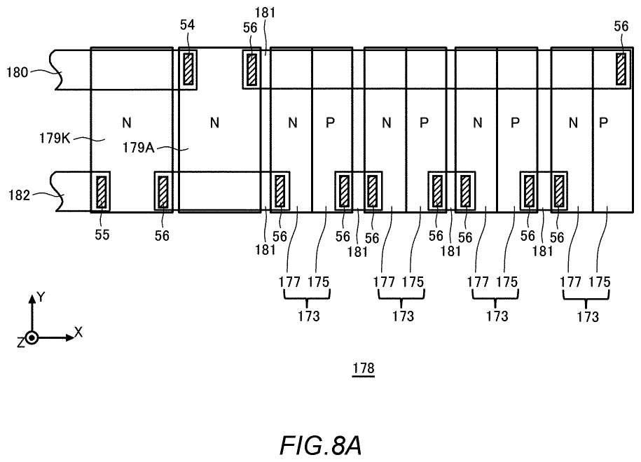

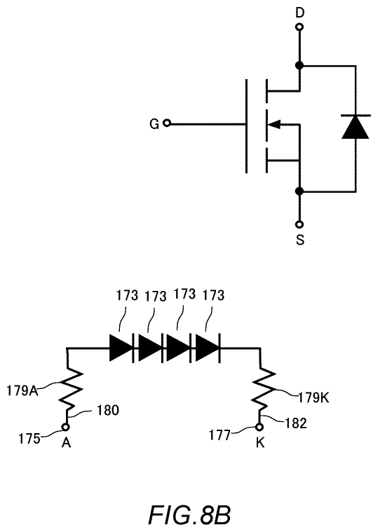

FIG. 8A illustrates another example of the top view of the temperature sensing unit 178 according to the example. FIG. 8B illustrates another example of the equivalent circuit of the semiconductor device 100. FIG. 8B illustrates an example of the equivalent circuit corresponding to the semiconductor device 100 including the temperature sensing unit 178 of FIG. 8A. In the description of FIGS. 8A and 8B, the description of elements common to those of FIG. 3A is omitted.

The resistance portion 179 of the present example includes an anode side resistance portion 179A provided between the anode wiring 180 and the temperature sensing diode portion 173, and a cathode side resistance portion 179K provided between the cathode wiring 182 and the temperature sensing diode portion 173.

The anode wiring 180 is connected to the anode side resistance portion 179A via the contact hole 54, and the anode side resistance portion 179A is connected to the anode portion 175 of the temperature sensing diode portion 173 farthest from the anode pad 174 (in +X axis direction) via the contact hole 56 and the connection portion 181. In addition, the cathode wiring 182 is connected to the cathode side resistance portion 179K via the contact hole 55, and the cathode side resistance portion 179K is connected to the cathode portion 177 of the closest temperature sensing diode portion 173 via the contact hole 56 and the connection portion 181.

The anode side resistance portion 179A and the cathode side resistance portion 179K may have the same doping concentration or different doping concentrations. The anode side resistance portion 179A and the cathode side resistance portion 179K may have the same dimension or different dimensions. In addition, in FIG. 8A, the anode side resistance portion 179A is provided in the +X axis direction with respect to the cathode side resistance portion 179K, but these positions may be reversed.

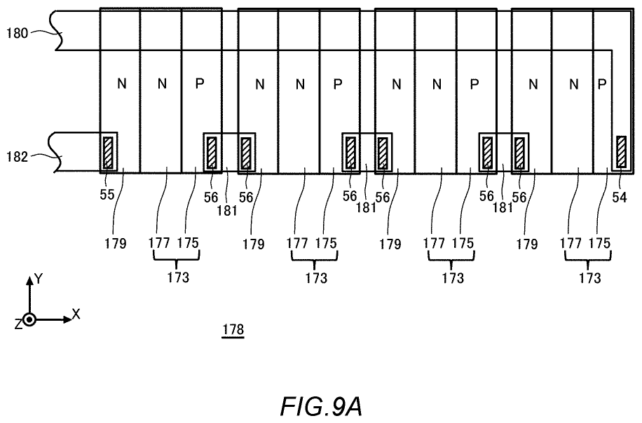

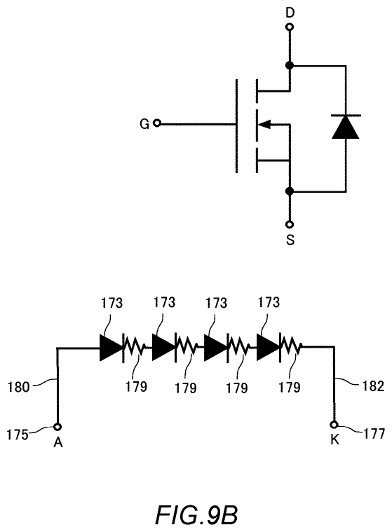

FIG. 9A illustrates another example of the top view of the temperature sensing unit 178 according to the example. FIG. 9B illustrates another example of the equivalent circuit of the semiconductor device 100. FIG. 9B illustrates an example of the equivalent circuit corresponding to the semiconductor device 100 including the temperature sensing unit 178 of FIG. 9A. In the description of FIGS. 9A and 9B, the description of elements common to those of FIG. 3A is omitted.

The resistance portion 179 of the present example is provided between the temperature sensing diode portions 173. That is, the resistance portions 179 are provided integrally with the cathode portions 177 of the temperature sensing diode portions 173. As a result, the X axis direction distance of the temperature sensing unit 178 is shortened, the area of the active portion 120 can be enlarged, and the number of the connection portions 181 and the contact holes 56 can be reduced.

In the example of FIGS. 8A to 9B, the conductive layer 185 and the second insulating film 37 as illustrated in FIG. 7C or 7D may be provided below the temperature sensing unit 178.

In this manner, the temperature sensing unit 178 of the present example has the resistance portion 179 of the N type having the same temperature dependency as the forward voltage V_{F} of the temperature sensing diode portion 173, and since the resistance value of the N type region is larger than the resistance value of the P type region, the variation amount ΔV_{F} of the forward voltage V_{F} in the forward current I₀ increases, and the temperature detection accuracy can be improved.

The temperature sensing unit 178 according to the above-described example includes the resistance portion 179 of the N type, but instead of this, metal such as aluminum or an alloy containing aluminum may be used as the resistance portion. In this case, the dimension (in particular, the length) of the resistance portion may be determined such that the total value of the resistances of the cathode portion 177 and the resistance portion becomes greater than the resistance of the anode portion 175. Alternatively, instead of providing the resistance portion in the temperature sensing unit 178, the extension lengths of the anode wiring 180 and the cathode wiring 182 may be increased.

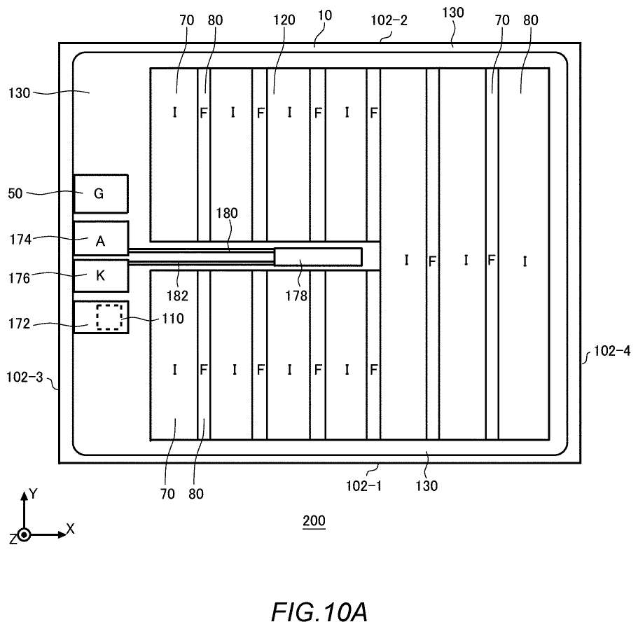

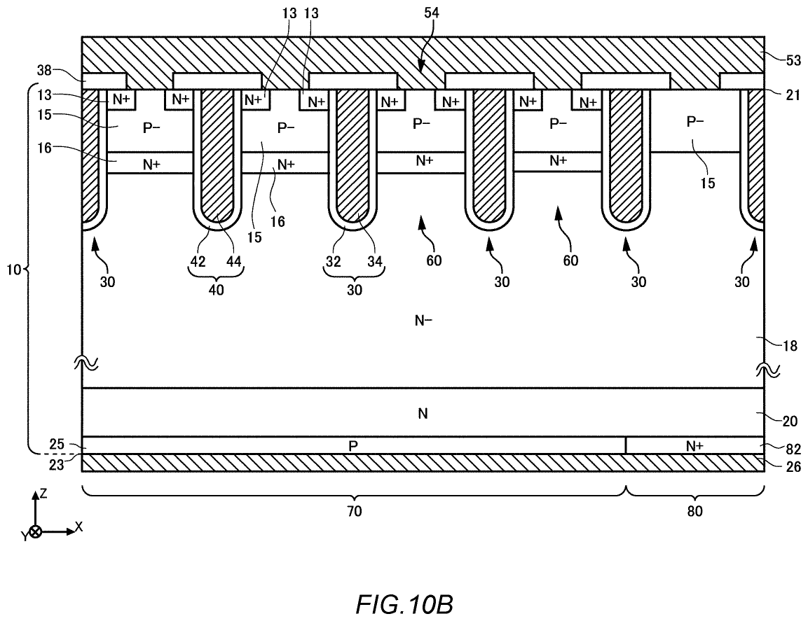

FIG. 10A illustrates an example of a top view of a semiconductor device 200 according to an example. The present example is different from FIG. 1 in that the transistor portion 70 including a transistor element such as an insulated gate bipolar transistor (IGBT) and a diode portion 80 including a diode element such as a freewheeling diode (FWD) are provided in the active portion 120.

When the IGBT and the FWD are provided in the active portion 120, the transistor portion 70 and the diode portion 80 form a reverse conducting IGBT (RC-IGBT). The active portion 120 may be a region in which at least one transistor portion 70 and at least one diode portion 80 are provided.

In the present example, in the active portion 120, a symbol “I” is attached to a region where the transistor portion 70 is arranged, and a symbol “F” is attached to a region where the diode portion 80 is arranged. The transistor portion 70 and the diode portion 80 may be alternately arranged side by side in the X axis direction in each region of the active portion 120.

FIG. 10B illustrates an example of an XZ cross-sectional view of the semiconductor device 200. FIG. 10B illustrates an example of an XZ cross-sectional view of the element structure in the transistor portion 70 and the diode portion 80 of the active portion 120.

The transistor portion 70 has a plurality of dummy trench portions 30 and a plurality of gate trench portions 40 on the front surface 21 of the semiconductor substrate 10, and the diode portion 80 includes a plurality of dummy trench portions 30. In addition, the semiconductor substrate 10 has the mesa portion 60 which is a dopant diffusion region between the plurality of trench portions. The mesa portion 60 is connected to an emitter electrode 53 via the contact hole 54.

The dummy trench portion 30 has a dummy insulating film 32 and the dummy conductive portion 34. The dummy conductive portion 34 is electrically connected to the emitter electrode 53 via the contact hole and set to have an emitter potential.

The gate trench portion 40 includes the gate conductive portion 44 composed of a conductor such as metal and a gate insulating film 42. The gate conductive portion 44 is insulated from the emitter electrode 53 by the interlayer insulating film 38. The gate conductive portion 44 is electrically connected to the gate pad 50 by the gate runner and set to have a gate potential. The gate conductive portion 44 corresponds to the gate electrode of the transistor portion 70. As an example, the gate potential may be higher than the emitter potential.

The transistor portion 70 includes, in order from the front surface 21 side of the semiconductor substrate 10, an emitter region 13 of the first conductivity type, a base region 15 of the second conductivity type, a drift region 18 of the first conductivity type, and a collector region 25 of the second conductivity type. The emitter region 13 may be provided over the entire mesa portion 60 on the front surface 21 of the semiconductor substrate 10, or may be provided only in a region close to the dummy trench portion 30 and the gate trench portion 40. In a region of in the mesa portion 60 where the emitter region 13 is not provided, the base region 15 may be exposed to the front surface 21.

In addition, the transistor portion 70 of the present example has an accumulation region 16 of the first conductivity type provided between the base region 15 and the drift region 18. By providing the accumulation region 16, the IE effect (Injection Enhancement effect) of carriers on the base region 15 can be improved, and an on-voltage can be reduced. Note that the accumulation region 16 may be omitted.

As an example, the emitter region 13 has an N+ type polarity. The base region 15 is different from the base region 14 of FIG. 2 in that the base region has a P-type polarity. When the gate conductive portion 44 is set to have the gate potential, electrons are attracted toward the gate trench portion 40 in the base region 15. A channel of the N type is formed in a region of the base region 15 in contact with the gate trench portion 40, and is driven as a transistor.

In the diode portion 80, the base region 15 of the P− type is provided on the front surface 21 side of the semiconductor substrate 10. The diode portion 80 of the present example is not provided with the accumulation region 16. In another example, the accumulation region 16 may also be provided in the diode portion 80.

The drift region 18 of the N−type is provided below the accumulation region 16 in the transistor portion 70 and below the base region 15 in the diode portion 80. In both the transistor portion 70 and the diode portion 80, a buffer region 20 of the N type is provided under the drift region 18. The buffer region 20 may function as a field stop layer that prevents a depletion layer extending from the lower surface of the base region 15 from reaching the collector region 25 of the P type and the cathode region 82 of the N+ type.

In the transistor portion 70, the collector region 25 of the P type is provided below the buffer region 20. In the diode portion 80, the cathode region 82 of the N+ type is provided below the buffer region 20.

The lower surfaces of the collector region 25 and the cathode region 82 correspond to the back surface 23 of the semiconductor substrate 10. A collector electrode 26 is provided on the back surface 23 of the semiconductor substrate 10. The collector electrode 26 is provided by a conductive material such as metal or by stacking conductive materials such as metal.

In the present example, the transistor portion 70 and the diode portion 80 are alternately arranged along the X axis direction, but the transistor portion 70 and the diode portion 80 may be alternately arranged along the Y axis direction.

Also in the semiconductor device 200 including the RC-IGBT in the active portion 120, the temperature sensing unit 178 illustrated in FIGS. 3A, 3B, 3C, 6A, 6C, 7A, 7B, 7C, 7D, 7E, 8A, and 9A can be provided. In this case, in the temperature sensing unit 178, the buffer region 20 is provided on the lower surface of the drift region 18, and the collector region 25 is provided on the lower surface of the buffer region 20.

The temperature sensing unit 178 can obtain the same effect as a case where the MOSFET is provided in the active portion 120. Further, the same applies to a case where the active portion 120 includes an insulated gate bipolar transistor (IGBT).

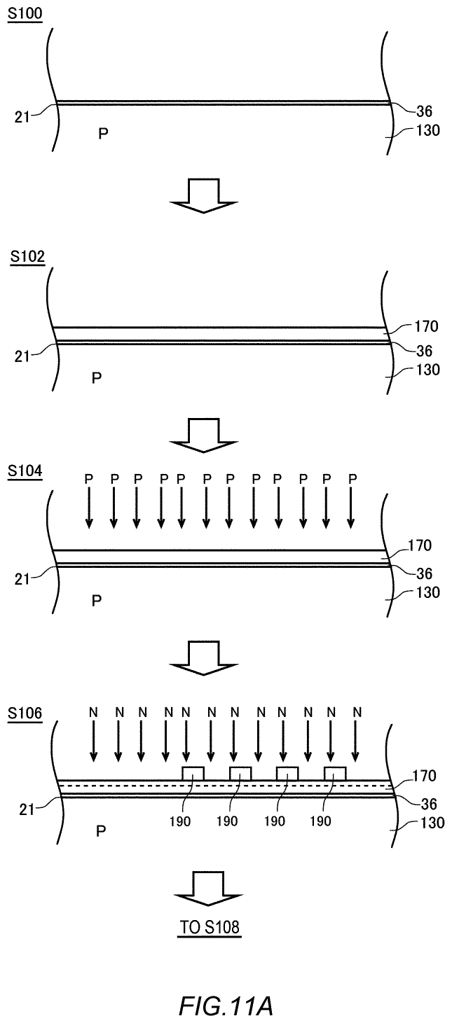

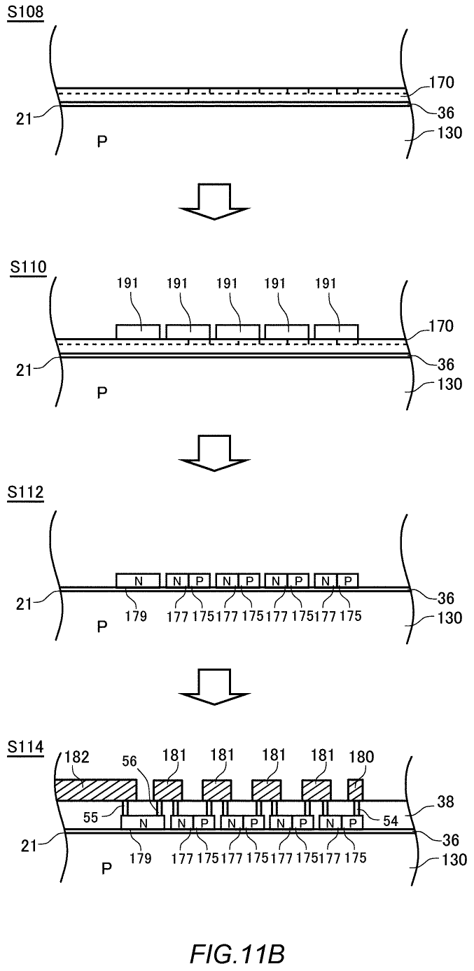

FIGS. 11A and 11B illustrate an example of a manufacturing method of the semiconductor device 100. Herein, a step of forming the temperature sensing unit 178 in FIG. 3A will be described. In step S100, the first insulating film 36 is formed on the front surface 21 of the semiconductor substrate 10 by thermal oxidation. A region where the temperature sensing unit 178 is formed may be a region where the well region 130 is provided on the front surface 21 of the semiconductor substrate 10.

The first insulating film 36 may be formed of the same oxide film as the gate insulating film 42. That is, the first insulating film 36 may be formed in the same step as the gate insulating film 42.

In step S102, a polysilicon layer 170 for forming the temperature sensing unit 178 is formed on the first insulating film 36 by a CVD method. The polysilicon layer 170 may be non-doped polysilicon or polysilicon of the N type with a low doping concentration.

In step S104, a P type impurity such as boron (B) is ion-implanted from above the front surface 21 of the semiconductor substrate 10. The P type impurity is ion-implanted into the entire surface of the polysilicon layer 170. The doping concentration of the P type impurity may be greater than or equal to 1E18 cm⁻³ and less than 1E20 cm⁻³.

Next, in step S106, a resist mask 190 is arranged on the polysilicon layer 170, and an N type impurity is selectively ion-implanted from above the front surface 21 of the semiconductor substrate 10 by using the resist mask 190. The N type impurity is arsenic (As), phosphorus (P), or the like. The doping concentration of the N type impurity may be greater than or equal to 1E18 cm⁻³ and less than 1E20 cm⁻³.

A region where the resist mask 190 is arranged corresponds to the P type region that finally becomes the anode portion 175. A region into which the N type impurity is ion-implanted corresponds to the N type region that finally becomes the cathode portion 177 or the resistance portion 179.

The N type impurity is ion-implanted with a dimension (width) such that the resistance of the N type region is larger than the resistance of the P type region. Note that the implantation depth of the P type impurity implanted in the previous step S104 is indicated by a broken line.

The doping concentration of the resistance portion 179 may be the same as the doping concentration of the cathode portion 177. In this case, the resistance portion 179 and the cathode portion 177 may be formed in the same step. That is, the regions to be the resistance portion 179 and the cathode portion 177 may be ion-implanted at the same doping concentration in step S106.

On the other hand, the doping concentration of the resistance portion 179 may be different from the doping concentration of the cathode portion 177. In this case, as the polysilicon layer 170, polysilicon having a doping concentration lower than the doping concentration to be ion-implanted in step S106 is used. In step S106, ions are implanted only into the region to be the cathode portion 177, and ions are not implanted into the region to be the resistance portion 179.

In step S108, the resist mask 190 is removed. In step S110, the implanted N type and P type impurities are diffused from the upper surface to the lower surface of the polysilicon layer 170 by heat treatment. In addition, a resist mask 191 is arranged on the polysilicon layer 170, and etching is performed using the resist mask 191, whereby the polysilicon layer 170 is patterned.

In step S112, the resist mask 191 is removed, and the plurality of temperature sensing diode portions 173 having the anode portion 175 and the cathode portion 177 and the resistance portion 179 of the N type are formed.

In step 114, after the interlayer insulating film 38 is formed to cover the resistance portion 179, the anode portion 175, and the cathode portion 177, the contact holes 54, 55, and 56 are formed by patterning the interlayer insulating film 38. Next, the anode wiring 180, the cathode wiring 182, and the connection portion 181 are formed by patterning a metal layer of aluminum, an alloy containing aluminum, or the like arranged on the interlayer insulating film 38.

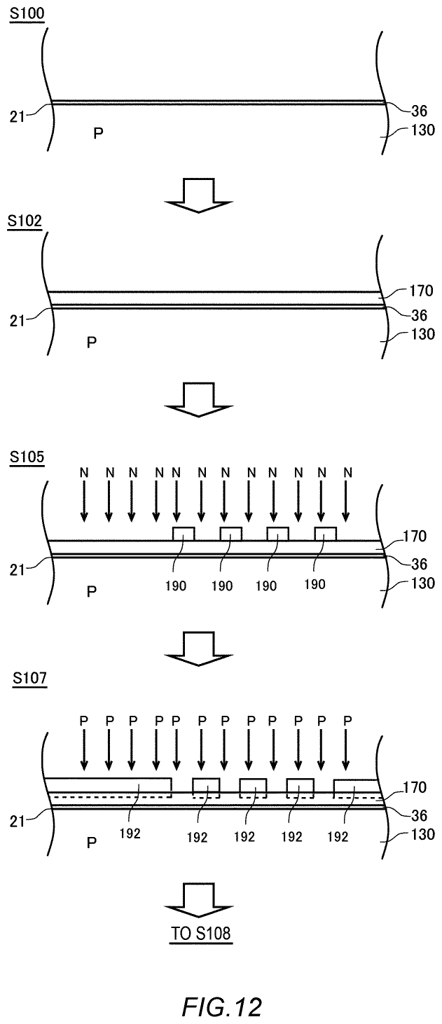

FIG. 12 illustrates another example of the manufacturing method of the semiconductor device 100. Herein, similarly to FIGS. 11A and 11B, a step of forming the temperature sensing unit 178 in FIG. 3A will be described. Note that since steps S100 and S102 are common to those in FIG. 11A, the description thereof is omitted, and subsequent step S105 will be described.

In step S105, the resist mask 190 is arranged on the polysilicon layer 170, and an N type impurity such as arsenic (As), phosphorus (P), or the like is selectively ion-implanted from above the front surface 21 of the semiconductor substrate 10. A region where the resist mask 190 is arranged corresponds to the P type region that finally becomes the anode portion 175. A region into which the N type impurity is ion-implanted corresponds to the N type region that finally becomes the cathode portion 177 or the resistance portion 179.

Next, in step S107, the resist mask 190 is removed, the resist mask 192 is arranged on the polysilicon layer 170, and a P type impurity such as boron (B) is ion-implanted from above the front surface 21 of the semiconductor substrate 10. The resist mask 192 is arranged in the region into which the N type impurities have been ion-implanted in step S105, that is, a region where the resist mask 190 has not been arranged.

In steps S105 and S107, the N type and P type impurities are ion-implanted with a dimension (width) such that the resistance of the N type region is larger than the resistance of the P type region. Step S108 and subsequent steps to be performed next are common to those in FIG. 11, and thus the description thereof is omitted.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate; 12: source region; 13: emitter region; 14: base region; 15: base region; 16: accumulation region; 18: drift region; 20: buffer region; 21: front surface; 22: drain region; 23: back surface; 24: drain electrode; 25: collector region; 26: collector electrode; 30: dummy trench portion; 32: dummy insulating film; 34: dummy conductive portion; 36: first insulating film; 37: second insulating film; 38: interlayer insulating film; 40: gate trench portion; 42: gate insulating film; 44: gate conductive portion; 50: gate pad; 52: source electrode; 53: emitter electrode; 54: contact hole; 55: contact hole; 56: contact hole; 60: mesa portion; 70: transistor portion; 80: diode portion; 82: cathode region; 100: semiconductor device; 102: end side; 110: current sensing unit; 120: active portion; 130: well region; 170: polysilicon layer; 172: current sensing pad; 173: temperature sensing diode portion; 174: anode pad; 175: anode portion; 176: cathode pad; 177: cathode portion; 178: temperature sensing unit; 179: resistance portion; 180: anode wiring; 181: connection portion; 182: cathode wiring; 183: connection portion; 185: conductive layer; 190: resist mask; 191: resist mask; 192: resist mask; 200: semiconductor device

What is claimed is:

1. A semiconductor device comprising:
a temperature sensing unit provided above a front surface of a semiconductor substrate, wherein
the temperature sensing unit includes a temperature sensing diode portion and a resistance portion of an N type electrically connected to the temperature sensing diode portion,
the temperature sensing diode portion includes an anode portion and a cathode portion coupled to the anode portion,
a plurality of the temperature sensing diode portions is connected in series, and
a sum of resistance values of the cathode portion and the resistance portion is greater than a resistance value of the anode portion.

2. The semiconductor device according to claim 1, wherein
the resistance portion is polysilicon of the N type.

3. The semiconductor device according to claim 1, wherein
the plurality of temperature sensing diode portions connected in series further includes:
an anode wiring electrically connected to the anode portion; and
a cathode wiring electrically connected to the cathode portion, and
the resistance portion is provided between the anode wiring and the plurality of temperature sensing diode portions connected in series.

4. The semiconductor device according to claim 2, wherein
the plurality of temperature sensing diode portions connected in series further includes:
an anode wiring electrically connected to the anode portion; and
a cathode wiring electrically connected to the cathode portion, and
the resistance portion is provided between the anode wiring and the plurality of temperature sensing diode portions connected in series.

5. The semiconductor device according to claim 1, wherein
the plurality of temperature sensing diode portions connected in series further includes:
an anode wiring electrically connected to the anode portion; and
a cathode wiring electrically connected to the cathode portion, and
the resistance portion is provided between the cathode wiring and the plurality of temperature sensing diode portions connected in series.

6. The semiconductor device according to claim 1, wherein
the plurality of temperature sensing diode portions connected in series further includes:
an anode wiring electrically connected to the anode portion; and
a cathode wiring electrically connected to the cathode portion, and
the resistance portion includes:
an anode side resistance portion provided between the anode wiring and the plurality of temperature sensing diode portions connected in series; and
a cathode side resistance portion provided between the cathode wiring and the plurality of temperature sensing diode portions connected in series.

7. The semiconductor device according to claim 1, wherein
the resistance portion is provided between the temperature sensing diode portions.

8. The semiconductor device according to claim 1, wherein
the resistance portion is provided to be coupled to the cathode portion.

9. The semiconductor device according to claim 1, wherein
the anode portion and the cathode portion are arrayed on a surface parallel to the front surface of the semiconductor substrate.

10. The semiconductor device according to claim 1, wherein
a doping concentration of the resistance portion is greater than or equal to 1E18 cm⁻³ and less than 1E20 cm⁻³.

11. The semiconductor device according to claim 1, wherein
a doping concentration of the temperature sensing diode portion is greater than or equal to 1E18 cm⁻³ and less than 1E20 cm⁻³.

12. The semiconductor device according to claim 1, wherein
a doping concentration of the resistance portion is equal to or less than a doping concentration of the cathode portion.

13. The semiconductor device according to claim 12, wherein
the doping concentration of the resistance portion is the same as the doping concentration of the cathode portion.

14. The semiconductor device according to claim 1, further comprising:
a first insulating film provided on the front surface of the semiconductor substrate; a conductive layer provided on the first insulating film; and a second insulating film covering the conductive layer, wherein
the temperature sensing unit is provided on the second insulating film.

15. The semiconductor device according to claim 14, wherein
the conductive layer is polysilicon of the N type.

16. The semiconductor device according to claim 15, wherein
a doping concentration of the conductive layer is greater than or equal to 1E20 cm⁻³.

17. The semiconductor device according to claim 14, wherein
the conductive layer has a plurality of regions arranged correspondingly to the temperature sensing diode portions and the resistance portion and divided from each other.

18. A manufacturing method of a semiconductor device comprising:
forming, above a front surface of a semiconductor substrate, a temperature sensing unit including a plurality of temperature sensing diode portions and a resistance portion of an N type, the plurality of temperature sensing diode portions being connected in series and each including an anode portion and a cathode portion coupled to the anode portion, the resistance portion being electrically connected to the plurality of temperature sensing diode portions, wherein
a sum of resistance values of the cathode portion and the resistance portion is greater than a resistance value of the anode portion.

19. The manufacturing method of a semiconductor device according to claim 18, wherein
a doping concentration of the resistance portion is the same as a doping concentration of the cathode portion, and
the resistance portion and the cathode portion are formed in a same process.

20. The manufacturing method of a semiconductor device according to claim 18, wherein
a doping concentration of the resistance portion is different from a doping concentration of the cathode portion, and the resistance portion is formed, without ion implantation, of polysilicon of the N type having a doping concentration lower than that of the cathode portion.
